(19) United States
(12) Patent Application Publication
(10) Pub. No.: US 2014/0060330 A1
(43) Pub. Date: Mar. 6, 2014

(54) MICROPOROUS MEMBRANE AND FINE-FIBER LAMINATE

(71) Applicant: DONALDSON COMPANY, INC., (US)

(72) Inventors: Alexandra MB Boyat, Minneapolis, MN (US); Michael J. Hebert, St. Paul, MN (US); Thomas M. Weik, Deephaven, MN (US); Robert O. Nelson, Rosemount, MN (US); Lloyd G. Keleny, Champlin, MN (US); Jacob Sanders, Burnsville, MN (US)

(73) Assignee: DONALDSON COMPANY, INC., Minneapolis, MN (US)

(21) Appl. No.: 13/839,283

(22) Filed: Mar. 15, 2013

Related U.S. Application Data
(60) Provisional application No. 61/697,251, filed on Sep. 5, 2012.

(51) Int. Cl. H05K 5/02

(52) U.S. Cl. CPC H05K 5/0213
USPC 96/11; 156/62.4

(57) ABSTRACT

Taught herein is a venting media laminate having a microporous membrane layer, a fine fiber layer directly coupled to the microporous membrane layer, and a colorant disposed in the fine fiber layer. Also described is an acoustic venting assembly with a microporous membrane layer and a fine fiber layer having an average insertion loss no more than 100% more than the average insertion loss of the microporous membrane layer alone in the frequency range from 300 to 4000 Hz. Methods of manufacturing venting media is also described, where a colorant is added to the polymer solution which is spun to form a fine fiber layer. The fine fiber layer is laminated to an expanded PTFE membrane.

This application is a non-provisional application claiming priority to U.S. Provisional Application No. 61/697,251, filed Sep. 5, 2012, and the entire contents of which is incorporated herein by reference.

### FIELD OF THE INVENTION

The technology described herein generally relates to a laminate. More particularly, the technology described herein relates to a microporous membrane and fine fiber laminate.

### BACKGROUND

For a variety of electronics, exposure to water is of concern due to water damage that can occur. For this reason, many companies are transitioning to product designs that are waterproof that offer oleo and hydrophobicity. In doing so, such products also maintain clear acoustics for the microphones and speakers that are present in the device. Manufacturers would like to rate their products with a minimum of IPx7. This rating specifies that their products could survive being submerged to a depth of 1 meter for ½ hour without damage. A filter or vent is necessary for electronic devices to allow for pressure equalization, allowing the transducers to function properly.

Filters containing expanded polytetrafluoroethylene (ePTFE) are available to provide the necessary water protection for microphones and speakers. Acoustic vents are used to protect speakers and microphones from water and dust. Often these vents consist of expanded PTFE membranes. The PTFE membrane prevents water and/or dust from reaching the microphone or speaker, while also allowing the acoustic signal to pass through with minimal loss.

PTFE membranes are used because they can be manufactured to have low basis weight and high flexibility. These properties allow them to vibrate easily when excited by an acoustic signal, and transmit the acoustic signal to the other side without allowing liquid intrusion. In addition, PTFE membranes are gas permeable, allowing equalizations of differential pressures due to temperature changes, as well as the evacuation of moisture due to condensation. PTFE membrane also has high dust efficiency and can withstand high differential water pressure without any liquid water passing through.

Typically, such vents take the form of a disc being secured to the electronic housing covering a transducer. The industry has placed emphasis on achieving aesthetic goals such as filter color and vents that are less prone to damage and fouling, while maintaining standards for acoustic performance, airflow, and filtering ability.

Supportive woven and/or nonwoven substrates have been used to meet requirements such as filter color and reducing the risk of damaging and fouling of the vent. Laminate designs are generally expected to drastically negatively affect acoustic performance as the basis weight of the laminate is increased. FIG. 15 depicts the generally expected Insertion Loss results of two different laminates compared to ePTFE only. PES 100 and PES50 are two nonwoven scrims with different basis weight laminated to ePTFE. PES 50 has a basis weight of 1.0 ounces per square yard, whereas PES 100 has a basis weight of 2.2 ounces per square yard. For both scenarios, significant increase in insertion loss is observed after lamination. These results are consistent with what has generally been expected in the art.

### SUMMARY OF THE INVENTION

The technology described herein generally relates to venting media laminates. In one embodiment, the technology described herein is a venting media laminate having a microporous membrane layer, a fine fiber layer directly coupled to the microporous membrane layer, and a colorant disposed in the fine fiber layer.

In another embodiment, the technology described herein is a method of manufacturing venting media. An expanded PTFE membrane is provided and a polymer solution is formed. A colorant is added to the polymer solution which is spun to form a fine fiber layer. The fine fiber layer is laminated to the expanded PTFE membrane.

In yet another embodiment, the technology described herein is an acoustic venting assembly with a microporous membrane layer and a fine fiber layer directly coupled to the microporous membrane layer. The acoustic venting assembly has an insertion loss no more than 100% more than the average insertion loss of the microporous membrane layer alone in the frequency range from 300 to 4000 Hz.

### BRIEF DESCRIPTION OF THE DRAWINGS

FIG. 1 depicts a schematic of an example implementation of the current technology.

FIG. 2 is a front view of an example acoustic venting assembly of FIG. 1.

FIG. 3 is a cross-sectional view of the acoustic venting assembly of FIG. 2 along the line 3-3.

FIG. 4 depicts a schematic cross-sectional view of a laminate consistent with the technology disclosed herein.

FIG. 5 depicts an example system for formation of fine fibers.

FIG. 6 depicts a schematic cross-sectional view of another laminate consistent with the technology disclosed herein.

FIG. 7 depicts a schematic cross-sectional view of yet another laminate consistent with the technology disclosed herein.

FIG. 8 depicts a schematic cross-sectional view of yet another laminate consistent with the technology disclosed herein.

FIG. 9 depicts a flow chart consistent with the technology disclosed herein.

FIG. 10 depicts a schematic of a system.

FIG. 11 is a front view of another example of an acoustic venting assembly having a molded portion on one side.

FIG. 12 is a cross-sectional view of the acoustic venting assembly of FIG. 11 along the line 12-12.

FIG. 13 is a front view of yet another example acoustic venting assembly having a molded portion that extends to both sides.

FIG. 14 is a cross-sectional view of the acoustic venting assembly of FIG. 13 along the line 14-14.

FIG. 15 depicts the insertion losses of two samples and a PTFE membrane.

FIG. 16 depicts the insertion losses of two additional samples and a PTFE membrane.

FIG. 17 depicts an SEM micrograph of a fine fiber layer at 1000× magnification.

FIG. 18 depicts SEM micrograph of heat laminated fine fiber to an ePTFE membrane at 2,500× magnification.

FIG. 19 is a chart depicting the fiber distribution of a sample.

FIG. 20 depicts SEM micrograph of black fine fiber to an ePTFE membrane at 2,000× magnification.

FIG. 21 depicts SEM micrograph of polyurethane fine fiber at 1,000× magnification.

FIG. 22 depicts SEM micrograph of polyurethane fine fiber after an oleophobic treatment at 1,000× magnification.

FIG. 23 depicts a cross-sectional view of a test cap consistent with experimental testing described herein.

FIG. 24 is a graph depicting results for example control tests for frequency response.

The invention may be more completely understood and appreciated in consideration of the following detailed description of various embodiments of the invention in connection with the accompanying drawings.

### DETAILED DESCRIPTION

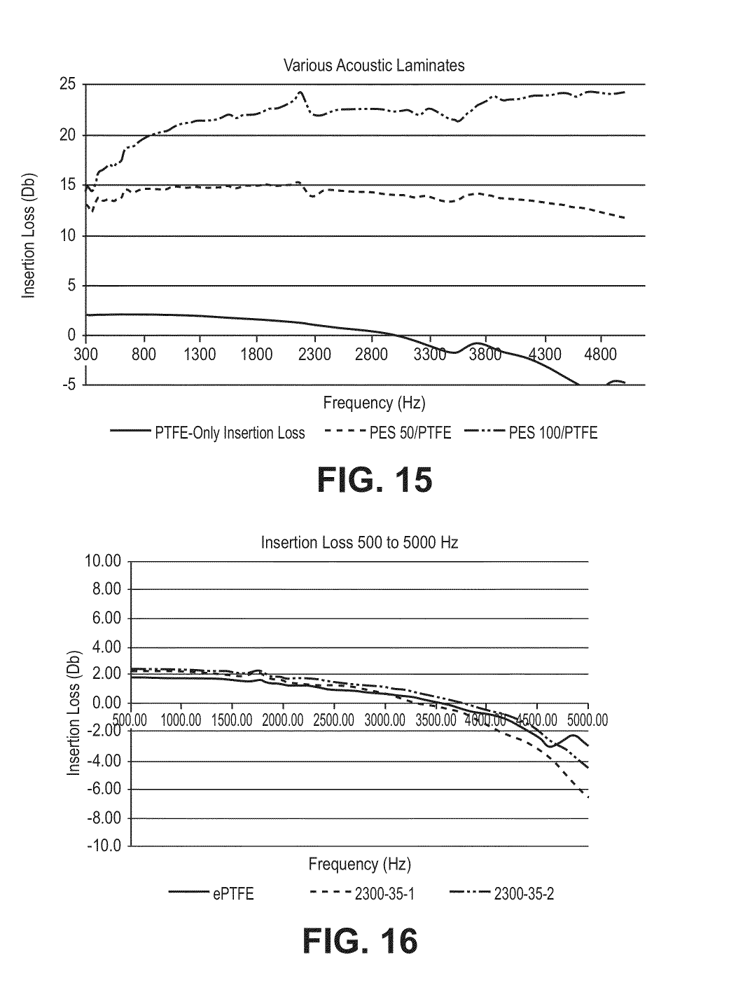

The technology encompassed by the current disclosure generally demonstrates that laminates can be used in the context of acoustic venting applications, potentially with a relatively negligible effect on acoustic performance, by tailoring material properties and the basis weight of a fine fiber matrix configured to be laminated to a microporous membrane. FIG. 16 depicts insertion loss results of laminate samples 2300-35-1 and 2300-35-2 with fine fiber spun directly to ePTFE membrane, and the insertion loss of the ePTFE membrane alone. As depicted, there is a relatively small effect on insertion loss compared to the sample response depicted in FIG. 15.

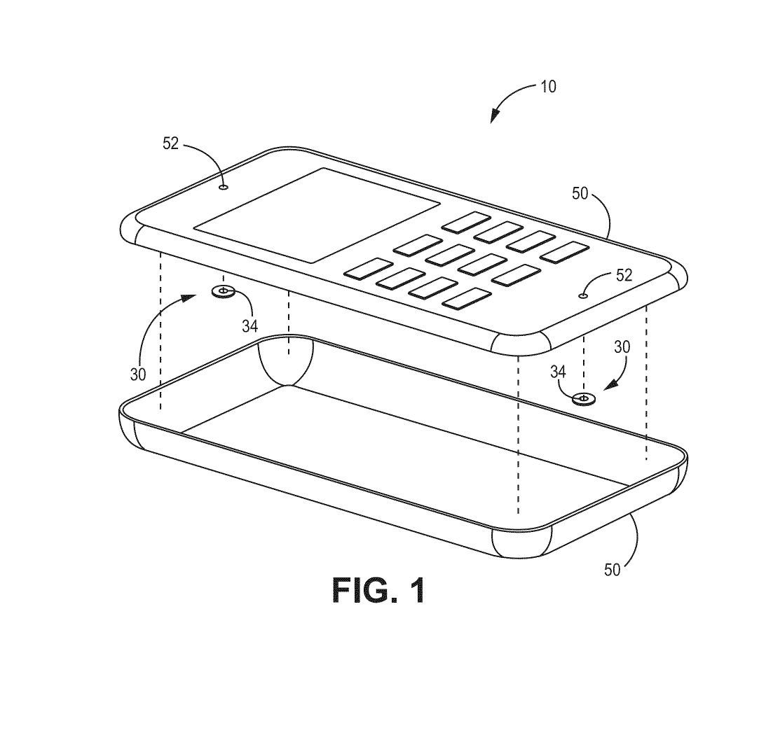

FIG. 1 depicts a schematic of an example implementation of the current technology. An electronic assembly 10 has an enclosure 50 defining at least one opening 52 with an acoustic venting assembly 30 sealably disposed across each opening 52. The acoustic venting assembly 30 is generally configured to prevent entry of particulates and water through the opening 52 of the enclosure 50 and accommodate acoustic pressure waves passing through. The filtering efficiency of the acoustic venting assembly 30 is generally no less than 99% with particle size greater than or equal to 0.3 micron traveling at 10.5 ft/min. The electronic assembly 10 has an Ingress Protection Rating of at least IPx7. The second number 7 in the IPx7 rating indicates that ingress of water in harmful quantities shall not be possible when the enclosure is immersed in up to 1 meter of water for 30 minutes. Test procedures are further defined in an international standard published by the International Electrotechnical Commission (IEC) and referred to as international standard IEC 60529. The first digit x in the IPx7 rating refers to the protection provided against the intrusion of solid objects and dust, and the level of protection is unspecified when an “x” is used in place of a number.

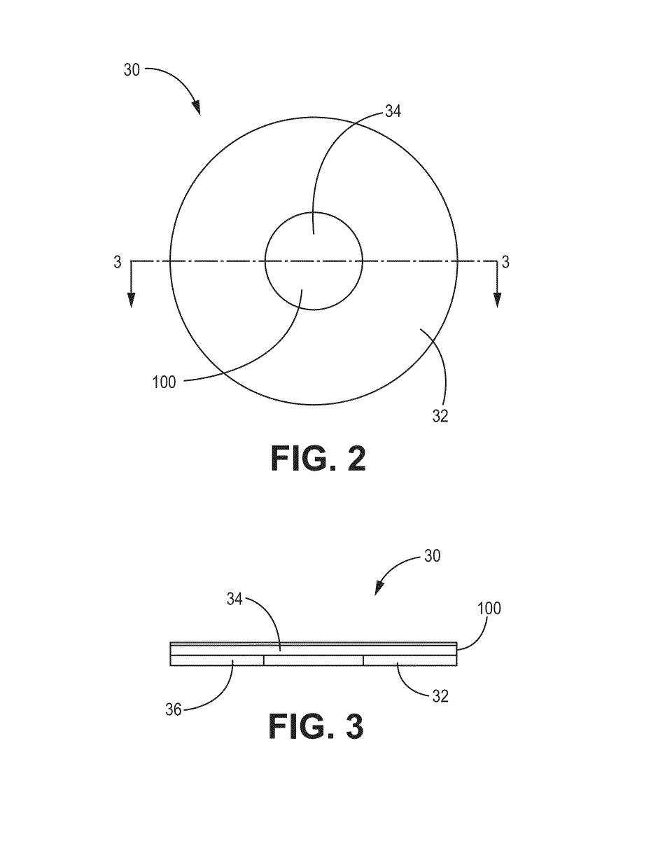

FIG. 2 depicts a front view of an example acoustic venting assembly consistent with the implementation depicted in FIG. 1, and FIG. 3 depicts a cross-sectional view of the acoustic venting assembly in FIG. 2. The acoustic venting assembly 30 generally defines a perimeter region 32 that is configured to couple to the electronics enclosure 50 about the opening 52 (See FIG. 1) and also defines an inner region 34 that allows sound transmission through a venting media laminate 100. In FIGS. 2 and 3, the venting media laminate 100 extends across the perimeter region 32 and the inner region 34. An adhesive 36 is disposed in the perimeter region 32, leaving the inner region 34 adhesive-free. The adhesive layer can be on one or both sides of the laminate 100. The acoustic venting assembly 30 can include additional layers and combinations of layers such as foam layers, adhesive layers, and gasket layers, as is generally known in the art.

While FIGS. 1-3 depict the overall shape of the acoustic venting assembly 30 and the inner region 34 as circular, those having skill in the art will appreciate that the acoustic venting assembly and its inner region can have a variety of shapes that are consistent with the technology disclosed herein. For example, the acoustic venting assembly and/or its inner region could have an ovular shape or a rectangular shape. In at least one embodiment the acoustic venting assembly can define two inner regions.

As used herein, the term laminate used as a noun means a structure made up of at least two layers of material. The term laminate used as a verb means to create a structure made up of at least two layers of material, whether or not the layers are created separately and then joined together and whether or not one layer is formed upon another layer.

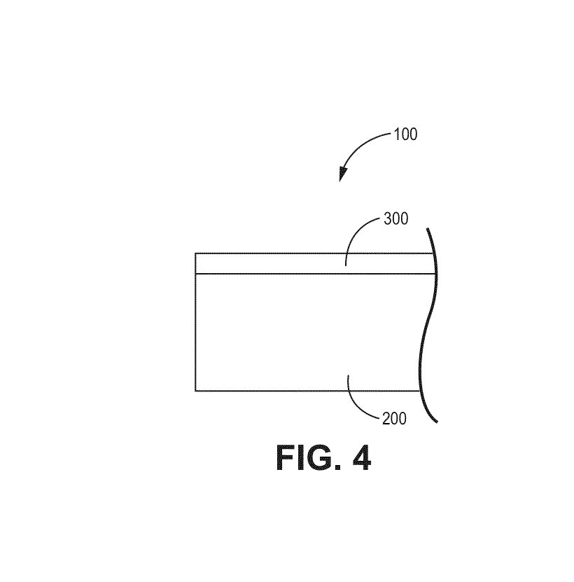

According to the current technology, the acoustic venting assembly 30 incorporates a venting media laminate having a variety of structures, including those consistent with any of FIGS. 4, and 6-8. The insertion loss of the acoustic venting assembly is substantially similar to the insertion loss of the microporous membrane layer alone as illustrated in FIG. 16.

In some embodiments, the laminate has an insertion loss based on average insertion loss from about 2 dB to about 10 dB in the range of 300 Hz to 4000 Hz. In at least one embodiment, the laminate has an average insertion loss of less than 5 dB in the frequency range from 300 Hz to 4000 Hz. Generally, the average insertion loss of the acoustic venting assembly is not more than 100% more than the average insertion loss of the microporous membrane layer alone in the frequency range from 300 Hz to 4000 Hz. In some embodiments the average insertion loss of the acoustic venting assembly is not more than 90%, 60%, 40%, 20%, or even 10% more than the average insertion loss of the microporous membrane layer alone in the frequency range from 300 Hz to 4000 Hz. The average H1 frequency response measurement and insertion loss will now be described.

### H1 Frequency Response and Insertion Loss

In general, frequency response is a quantitative measure of the output spectrum of a system or device in response to stimulus. It is a measure of the magnitude and phase of the output as a function of the frequency, in comparison to the input. In the context of an acoustic vent, the frequency response function (FRF) is a measure of the magnitude and phase of acoustic waves that have passed through the acoustic vent in comparison to the acoustic waves before they pass through the acoustic vent at each frequency across a particular acoustic range.

In one example of an experimental test for the H1 frequency response function of an acoustic-vent-of-interest, random acoustic signals, such as white noise, is generated via a loud speaker inside an anechoic test chamber. Two microphones are installed in the chamber to measure the acoustic signal, a reference microphone and an output microphone. Each of the microphones has a cap installed over the active area of the microphone, and the cap of the output microphone has the acoustic-vent-of-interest installed on the cap. The cap installed over the reference microphone lacks an acoustic vent. As such, the acoustic signals received through the reference microphone, which does not pass through any acoustic vent, is interpreted as equivalent to the acoustic signal prior to passing through the acoustic-vent-of-interest, and is accordingly designated the input data, or reference data, by the processing software. The acoustic signals received through the output microphone, which did pass through the acoustic-vent-of-interest, are designated as output data. The acoustic signals from the two microphones are then compared by the software to generate an H1 FRF across the spectrum.

Consistent with the experimental set up described above, one analysis system that can be used is the PULSE Analyzer Platform by Brüel & Kjær Sound & Vibration Measurement A/S located in Nærum, Denmark. The speaker is powered by the PULSE Analyzer Platform software to produce white noise. Brüel & Kjær type 2670 microphones can be used with the PULSE Analyzer Platform to administer this test. The PULSE Analyzer Platform software records microphone data for 5 seconds and averages the result across the frequency range. Acoustic data from the reference microphone is compared to the acoustic data from the output microphone by the PULSE Analyzer Platform software using the H1 FRF (frequency response function) calculation method which provides an output value in decibels (dB) at intervals across a frequency range. The lower the frequency response is for an acoustic vent in decibels, the better the sound transmission through the vent.

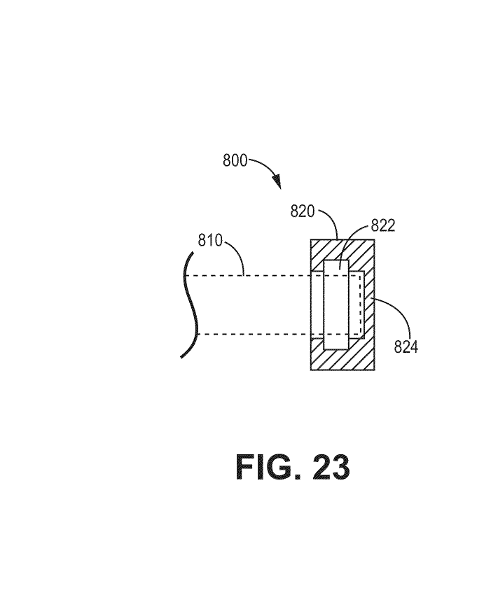

FIG. 23 depicts a cross-sectional view of an example test cap 800, installed over a first microphone 810. An O-ring is disposed in an opening 822 defined by the cap 800, which creates a seal between the cap 800 and the microphone 810. Although not depicted in the current figure, an opening is machined in the axial center of the back wall 824 of the cap 800 to match the size and shape of the vent being tested, where the vent is installed similarly to how the vent would be installed over the opening defined by an electronics housing, as explained above in the discussion of FIG. 1. Generally, the machined opening will match the size and shape of the adhesive-free inner region portion of the acoustic-vent-of-interest, such as described above with respect to FIGS. 1-3, and the second test cap associated with the second microphone will have a substantially identical opening machined therein.

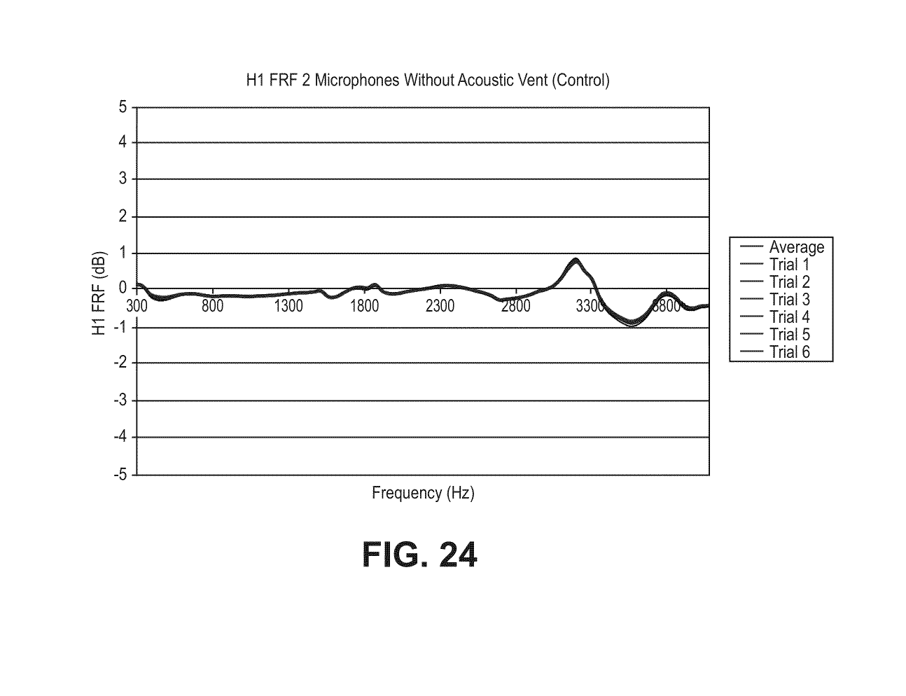

The H1 FRF calculation primarily demonstrates a loss in acoustic signal that is attributed to the acoustic vent. However, a small portion of the loss in acoustic signal is due to equipment imperfections between the two microphones, their positioning, and the sound field generated by the speaker. As such, it can be desirable to also run a control test to generate the H1 FRF control curve. Such an FRF control test has a similar test set-up as described above with regard to testing an acoustic-vent-of-interest, except each cap associated with the reference microphone and the output microphone lacks an acoustic vent. The H1 FRF calculation results are attributed to imperfections in the test setup. As such, in a perfect test, the H1 FRF will result in 0 dB across the spectrum. FIG. 24 depicts results associated with example control tests using the test equipment described above.

To calculate insertion loss, the control H1 FRF results adjust the test H1 FRF calculation results through the following equation:

IL(f)=H1ᵥₑₙₜ(f)−H1_{control}(f),

where IL(f) is the insertion loss; H1ᵥₑₙₜ(f) is the H1 FRF for the acoustic-vent-of-interest; and H1_{control}(f) is the H1 FRF for the control setup described above.

It will be appreciated by those having skill in the art that with a perfect, or near perfect, experimental setup the insertion loss will be numerically equivalent, or near equivalent, to the H1 FRF for an acoustic-vent-of-interest. But in practice, equipment quality can vary and therefore it is common to use insertion loss when determining the effect of a component on an acoustic signal. In this particular test procedure, the insertion loss is a comparison of FRF between microphones with and without an acoustic vent covering the output signal microphone.

As will be appreciated, the insertion loss results can be complex in nature. When attempting to compare the results of two different materials tested in an identical manner, it can be useful to calculate the average insertion loss in dB over a particular frequency range of interest. This is referred to as the average insertion loss. An equation for this calculation is given below:

$${IL}_{avg} = \frac{1}{4000 - 300} {\int }_{300 Hz}^{4000 Hz} \vert IL ( f ) \vert d f ,$$

where |IL(f)| is the absolute value of the insertion loss function at a given frequency f, and the frequency range is from 300 Hz to 4000 Hz. The absolute value of the insertion loss is used in the above equation to avoid inappropriately deflating the average insertion loss value (suggesting improved performance) resulting from negative insertion loss values in the spectrum.

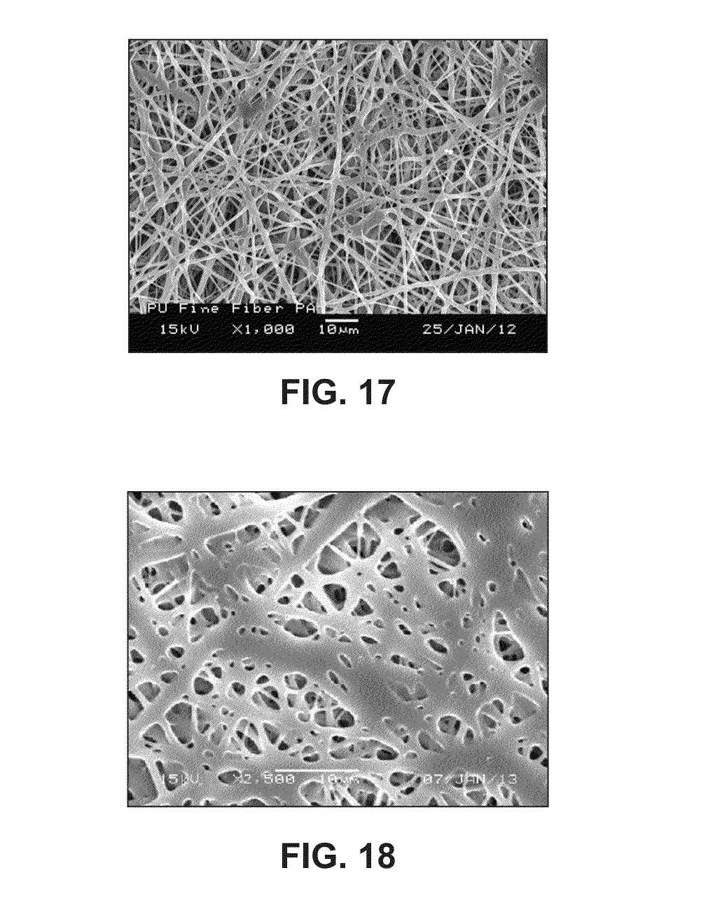

Returning back to the figures, the venting media laminate of the current application is generally a microporous membrane layer directly coupled to a fine fiber layer. One such example is depicted in FIG. 4, where a venting media laminate 100 for use as an acoustic venting assembly has microporous membrane layer 200 and a fine fiber layer 300. The fine fiber layer 300 is directly coupled to the microporous membrane layer 200, where the term “directly coupled” is defined as joined together without intervening substrates. The fine fiber layer 300 can be directly coupled to the microporous membrane layer 200 through calendaring, adhesive lamination, heat lamination, formation of the fine fiber layer directly on the microporous membrane layer, and the like. In a variety of embodiments, the lamination can augment the fine fiber morphology and diameter creating a fiber matrix with improved inter-fiber adhesion. FIGS. 17 and 18 are SEM micrographs of the fine fiber layer before and after lamination. As will be appreciated by those having skill in the art, FIG. 18 demonstrates a denser matrix after heat lamination compared to FIG. 17.

In multiple embodiments consistent with FIG. 4, the microporous membrane layer 200 is expanded polytetrafluoroethylene (ePTFE), although in other embodiments a different material having pores with diameters of about 2 microns or less than 2 microns could be used. In one embodiment the microporous membrane layer has a thickness from about 10 microns to about 100 microns. In embodiments where ePTFE is used in the microporous membrane layer, the ePTFE has an average pore size between 0.001 and 1.0 microns. In a variety of embodiments, the ePTFE has a porosity of greater than 10% by volume. In some embodiments, the ePTFE has a porosity of greater than 50% by volume.

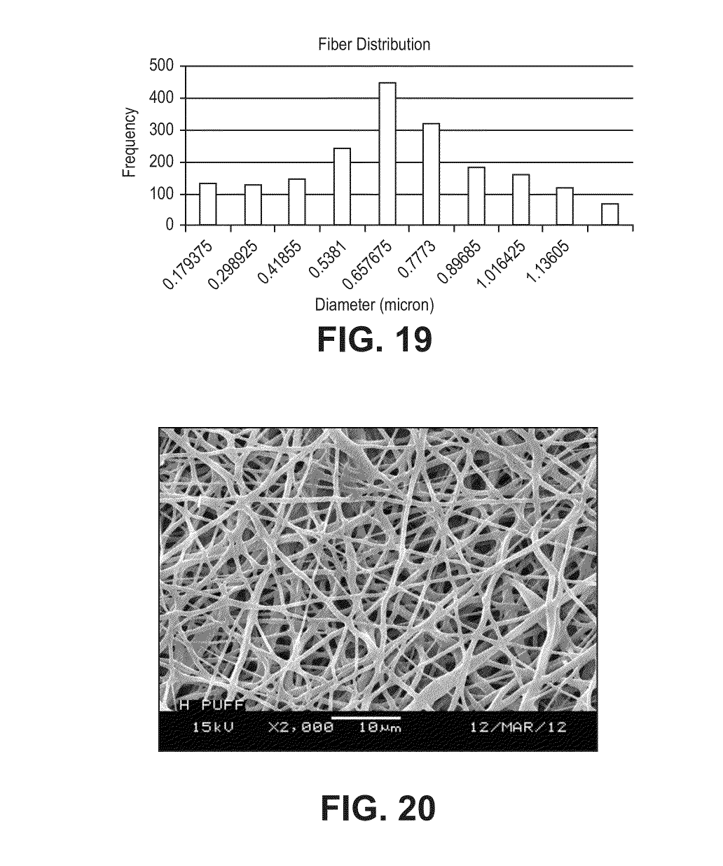

The fine fiber layer 300 is generally a layer constructed of a plurality of nonwoven, substantially randomized fibers. The fibers that comprise the fine fiber layer of the invention can include micro-fibers and nano-fibers with diameters no greater than about 5.0 microns, generally and preferably no greater than about 2 microns, and typically and have fiber diameters within the range of about 0.1 to 1.0 micron. FIG. 19 depicts an example fiber distribution of sample 2300-35-1 (sample 2300-35-1 is also referenced in FIG. 16) with diameters ranging from 0.18 micron to 1.13 micron.

Also, the fine fiber layer has an overall thickness that is no greater than about 50 microns, more preferably no more than 20 microns, most preferably no greater than about 5 microns, and typically and preferably that is within a thickness of about 1-8 times (and more preferably no more than 5 times) the average diameter of the fine fibers in the layer. Generally the fine fiber layer has a basis weight from about 0.0001 g-m⁻² to about 20 g-m⁻². More particularly, the fine fiber layer has a basis weight from about 0.0001 g-m⁻² to about 4.0 g-m⁻². In one embodiment, the fine fiber layer is self-supporting and, as such, does not require the use of an underlying substrate for handling.

Examples of materials for fine fiber layers, formation methods for fine fiber layers and methods for including particles in fine fiber layers are described in the following patents and patent applications, the contents of which are hereby incorporated by reference in their entireties: U.S. Provisional Application No. 61/537,171 (Attorney Docket No. 758.7149USP1) filed Sep. 21, 2011; U.S. Provisional Application 61/620,251 (Attorney Docket No. 444.71490161), filed Apr. 4, 2012; US Published Application No. 2012/0204527 (Attorney Docket No. 758.1149USC9) filed Aug. 17, 2011; U.S. Pat. No. 7,717,975 (Attorney Docket No. 758.1831USU1) issued on May 18, 2010; U.S. Pat. No. 7,655,070 (Attorney Docket No. 758.2034USU1), issued Feb. 2, 2010; and U.S. Published Application No. 2009/0247970 (Attorney Docket No. 758.7089USU1), filed Mar. 31, 2009.

In a variety of embodiments the fine fiber layer is polymeric. A number of polymer materials are consistent with the fine fiber layer. In one example, an aliphatic thermoplastic polyurethane (TPU) is used to form the fine fibers. In various embodiments, a polyurethane (PU) polyether used to form the fine fiber layer can be an aliphatic or aromatic polyurethane depending on the isocyanate used and can be a polyether polyurethane or a polyester polyurethane. A polyether urethane having desirable physical properties can be prepared by melt polymerization of a hydroxyl-terminated polyether or polyester intermediate and a chain extender with an aliphatic or aromatic (MDI) diisocyanate. The hydroxyl-terminated polyether has alkylene oxide repeat units containing from 2 to 10 carbon atoms and has a weight average molecular weight of at least 1000. The chain extender is a substantially non-branched glycol having 2 to 20 carbon atoms. The amount of the chain extender is from 0.5 to less than 2 mole per mole of hydroxyl terminated polyether. It is preferred that the polyether polyurethane is thermoplastic and has a melting point of about 140 degrees Celsius to 250 degrees Celsius or greater (e.g., 150 degree Celsius to 250 degrees Celsius) with 180 degrees Celsius or greater being preferred.

### Fine Fiber Formation—Electro-Spinning

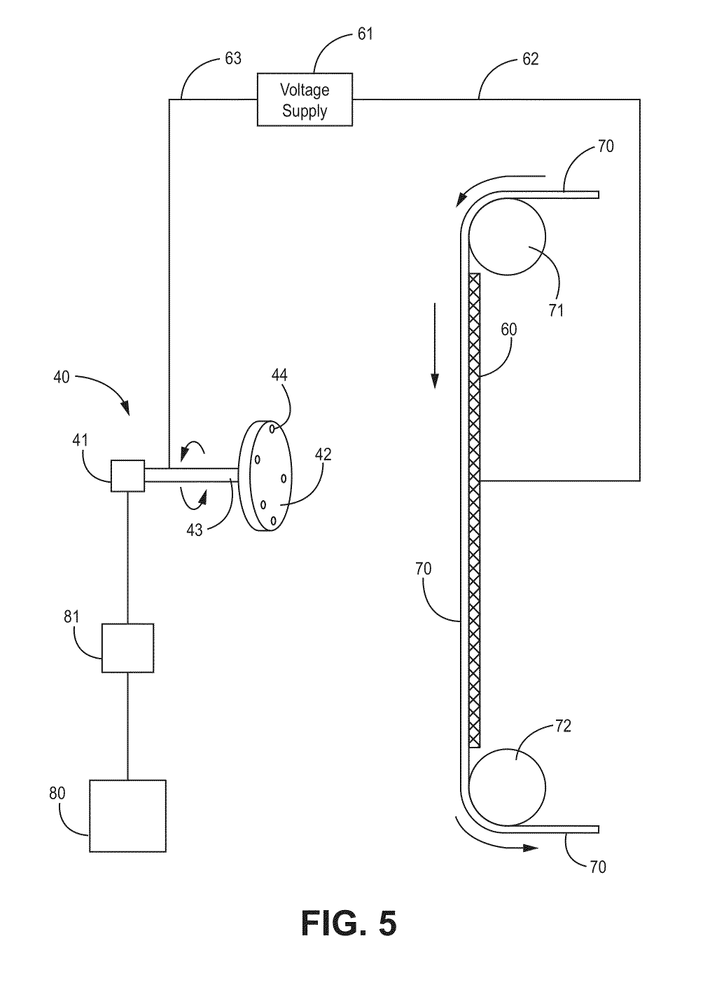

FIG. 5 depicts an example system for the formation of fine fibers. This system includes a reservoir 80 in which the fine fiber forming polymer solution is contained, a pump 81 and a rotary type emitting device or emitter 40 to which the polymeric solution is pumped. The emitter 40 generally consists of a rotating union 41, a rotating portion (or forward facing portion) 42 defining a plurality of offset holes 44 and a shaft 43 connecting the forward facing portion 42 and the rotating union 41. The rotating union 41 provides for introduction of the polymer solution to the forward facing portion 42 through the hollow shaft 43. The holes 44 are spaced around the periphery of the forward facing portion 42. Alternatively, the rotating portion 42 can be immersed into a reservoir of polymer fed by reservoir 80 and pump 81. The rotating portion 42 then obtains polymer solution from the reservoir 80 and as it rotates in the electrostatic field, a droplet of the solution is accelerated by the electrostatic field toward the collecting media 70 as discussed below.

Facing the emitter 40, but spaced apart therefrom, is a substantially planar grid 60 upon which the collecting media 70, i.e. substrate or combined substrate is positioned. Air can be drawn through the grid 60. The collecting media 70 is passed around rollers 71 and 72 which are positioned adjacent opposite ends of grid 60. A high voltage electrostatic potential is maintained between emitter 40 and grid 60 by means of a suitable electrostatic voltage source 61 and connections 62 and 63 which connect respectively to the grid 60 and emitter 40.

In use, the polymer solution is pumped to the rotating union 41 or reservoir from reservoir 80. The forward facing portion 42 rotates while liquid exits from holes 44, or is picked up from a reservoir, and moves from the outer edge of the emitter 40 toward collecting media 70 positioned on grid 60. Specifically, the electrostatic potential between grid 60 and the emitter 40 imparts a charge to the material which causes liquid to be emitted therefrom as thin fibers which are drawn toward grid 60 where they arrive and are collected on substrate 70 or an efficiency layer. In the case of the polymer in solution, solvent is evaporated off the fibers during their flight to the grid 60; therefore, the fibers arrive at the substrate 70 or efficiency layer. The fine fibers bond to the substrate fibers first encountered at the grid 60. Electrostatic field strength is selected to ensure that the polymer material as it is accelerated from the emitter 40 to the collecting media 70, the acceleration is sufficient to render the material into a very thin microfiber or nanofiber structure. Increasing or slowing the advance rate of the collecting media can deposit more or less emitted fibers on the forming media, thereby allowing control of the thickness of each layer deposited thereon. The rotating portion 42 can have a variety of beneficial positions. The rotating portion 42 can be placed in a plane of rotation such that the plane is perpendicular to the surface of the collecting media 70 or positioned at any arbitrary or desired angle. The rotating portion 42 can be positioned parallel to or slightly offset from parallel orientation.

While electro-spinning has been described herein, it will be appreciated by those having skill in the art that the fine fiber layer can be created using methods such as centrifugal-spinning, force-spinning, or meltblowing.

### Functional Layers

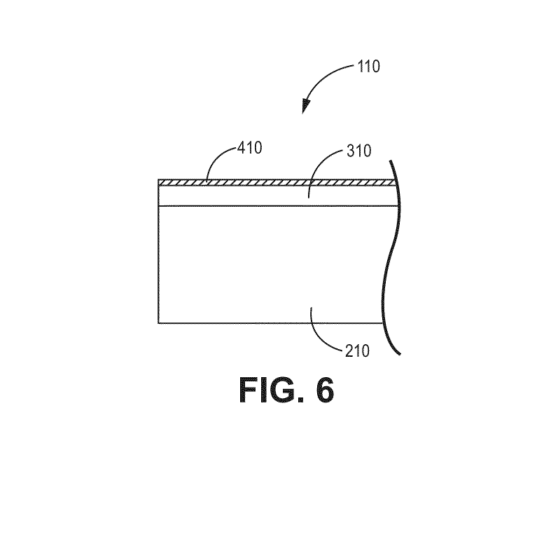

Referring back to the Figures, FIG. 6 depicts a schematic cross-sectional view of another laminate consistent with the technology disclosed herein. The laminate 110 has a microporous membrane layer 210, a fine fiber layer 310, and a functional layer 410 adjacent to the fine fiber layer 310. Although one functional layer 410 is depicted in FIG. 6, it will be appreciated that, in some embodiments, more functional layers can be incorporated. The functional layers are generally additives that can improve and/or change the properties of the laminate 110. Functional layers will now be described in detail.

Additive materials can substantially improve the fine fiber resistance to the effects of heat, humidity, impact, mechanical stress and other negative environmental effects. We have found that while processing the microfiber materials of the invention, that the additive materials can improve the oleophobic character, the hydrophobic character and can appear to aid in improving the chemical stability of the materials. The presence of oleophobic and hydrophobic additives in the current technology form a functional layer or protective coating, ablative surface or penetrate the surface to some depth to improve the nature of the polymeric material. We believe the important characteristics of these materials are the presence of a strongly hydrophobic group that can preferably also have oleophobic character. Strongly hydrophobic groups include fluorocarbon groups, hydrophobic hydrocarbon surfactants or blocks and substantially hydrocarbon oligomeric compositions. These materials are manufactured in compositions that have a portion of the molecule that tends to be compatible with the polymer material affording typically a physical bond or association with the polymer while the strongly hydrophobic or oleophobic group, as a result of the association of the additive with the polymer, forms a protective surface layer that resides on the surface or becomes alloyed with or mixed with the polymer surface layers.

For 0.2-micron fiber with 10% additive level, the surface thickness is calculated to be around 50 Å, if the additive has migrated toward the surface. Migration is believed to occur due to the incompatible nature of the oleophobic or hydrophobic groups in the bulk material. A 50 Å thickness appears to be reasonable thickness for protective coating. For 0.05-micron diameter fiber, 50 Å thickness corresponds to 20% mass. For 2 microns thickness fiber, 50 Å thickness corresponds to 2% mass. Preferably the additive materials are used at an amount of about 2 to 25 wt. %. Oligomeric additives that can be used in combination with the polymer materials of the invention include oligomers having a molecular weight of about 500 to about 5000, preferably about 500 to about 3000 including fluoro-chemicals, nonionic surfactants and low molecular weight resins or oligomers. Fluoro-organic wetting agents useful in this invention are organic molecules represented by the formula

R_{f}−G

wherein R_{f} is a fluoroaliphatic radical and G is a group which contains at least one hydrophilic group such as cationic, anionic, nonionic, or amphoteric groups. Nonionic materials are preferred. R_{f} is a fluorinated, monovalent, aliphatic organic radical containing at least two carbon atoms. Preferably, it is a saturated perfluoroaliphatic monovalent organic radical. However, hydrogen or chlorine atoms can be present as substituents on the skeletal chain. While radicals containing a large number of carbon atoms may function adequately, compounds containing not more than about 20 carbon atoms are preferred since large radicals usually represent a less efficient utilization of fluorine than is possible with shorter skeletal chains.

Preferably, R_{f} contains about 2 to 8 carbon atoms.

The cationic groups that are usable in the fluoro-organic agents employed in this invention may include an amine or a quaternary ammonium cationic group which can be oxygen-free (e.g., —NH₂) or oxygen-containing (e.g., amine oxides). Such amine and quaternary ammonium cationic hydrophilic groups can have formulas such as —NH₂, —(NH₃)X, —(NH(R²)₂)X, —(NH(R²)₃)X, or —N(R₂)₂→O, where x is an anionic counterion such as halide, hydroxide, sulfate, bisulfate, or carboxylate, R² is H or C₁₋₁₈ alkyl group, and each R² can be the same as or different from other R² groups. Preferably, R² is H or a C₁₋₁₆ alkyl group and X is halide, hydroxide, or bisulfate.

The anionic groups which are usable in the fluoro-organic wetting agents employed in various embodiments include groups which by ionization can become radicals of anions. The anionic groups may have formulas such as —COOM, —SO₃M, —OSO₃M, —PO₃HM, —OPO₃M₂, or —OPO₃HM, where M is H, a metal ion, (NR¹₄)⁺, or (SR¹₄)⁺, where each R¹ is independently H or substituted or unsubstituted C₁-C₆ alkyl. Preferably M is Na⁺ or K⁺. The preferred anionic groups of the fluoro-organo wetting agents used in various embodiments have the formula —COOM or —SO₃M. Included within the group of anionic fluoro-organic wetting agents are anionic polymeric materials typically manufactured from ethylenically unsaturated carboxylic mono- and diacid monomers having pendent fluorocarbon groups appended thereto. Such materials include surfactants obtained from 3M Corporation known as FC-430 and FC-431.

The amphoteric groups which are usable in the fluoro-organic wetting agent employed various embodiments include groups which contain at least one cationic group as defined above and at least one anionic group as defined above.

The nonionic groups which are usable in the fluoro-organic wetting agents employed various embodiments include groups which are hydrophilic but which under pH conditions of normal agronomic use are not ionized. The nonionic groups may have formulas such as —O(CH₂CH₂)ₓOH where x is greater than 1, —SO₂NH₂, —SO₂NHCH₂CH₂OH, —SO₂N(CH₂CH₂H)₂, CONH₂, —CONHCH₂CH₂OH, or —CON(CH₂CH₂OH)₂. Examples of such materials include materials of the following structure:

F(CF₂CF₂)ₙ—CH₂CH₂O—(CH₂CH₂O)ₘ—H

wherein n is 2 to 8 and m is 0 to 20.

Other fluoro-organic wetting agents include those cationic fluorochemicals described, for example in U.S. Pat. Nos. 2,764,602; 2,764,603; 3,147,064 and 4,069,158. Such amphoteric fluoro-organic wetting agents include those amphoteric fluorochemicals described, for example, in U.S. Pat. Nos. 2,764,602; 4,042,522; 4,069,158; 4,069,244; 4,090,967; 4,161,590 and 4,161,602. Such anionic fluoro-organic wetting agents include those anionic fluorochemicals described, for example, in U.S. Pat. Nos. 2,803,656; 3,255,131; 3,450,755 and 4,090,967.

Examples of such materials are duPont Zonyl FSN and duPont Zonyl FSO nonionic surfactants. Another aspect of additives that can be used in the polymers of the various embodiments include low molecular weight fluorocarbon acrylate materials such as 3M's Scotchgard® material having the general structure:

CF₃(CX₂)ₙ-acrylate

wherein X is —F or —CF₃ and n is 1 to 7.

Further, nonionic hydrocarbon surfactants including lower alcohol ethoxylates, fatty acid ethoxylates, nonylphenol ethoxylates, etc. can also be used as additive materials for the various embodiments. Examples of these materials include Triton X-100 and Triton N-101.

Useful materials for use as additive materials in the compositions of the various embodiments are tertiary butylphenol oligomers. Such materials tend to be relatively low molecular weight aromatic phenolic resins. Such resins are phenolic polymers prepared by enzymatic oxidative coupling. The absence of methylene bridges result in unique chemical and physical stability. These phenolic resins can be crosslinked with various amines and epoxies and are compatible with a variety of polymer materials. These materials are generally exemplified by the following structural formulas which are characterized by phenolic materials in a repeating motif in the absence of methylene bridge groups having phenolic and aromatic groups.

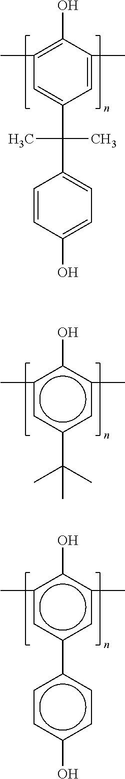

wherein n is 2 to 20. Examples of these phenolic materials include Enzo-BPA, Enzo-BPA/phenol, Enzo-TBP, Enzo-COP and other related phenolics were obtained from Enzymol International Inc., Columbus, Ohio.

Referring back to FIG. 6, the functional layer 410 can also change the coloration of the laminate through the use of a colorant layer, where the term “colorant” is defined as any additive that adjusts the perceived coloration of the fine fiber layer 310 and/or the laminate 110 itself, such as dyes, inks, pigments, and the like. In a variety of embodiments the functional layer 410 of FIG. 6 is a colorant disposed in the fine fiber layer 310. In one such embodiment the functional layer 410 is a dip coating of colorant in the fine fiber layer 310.

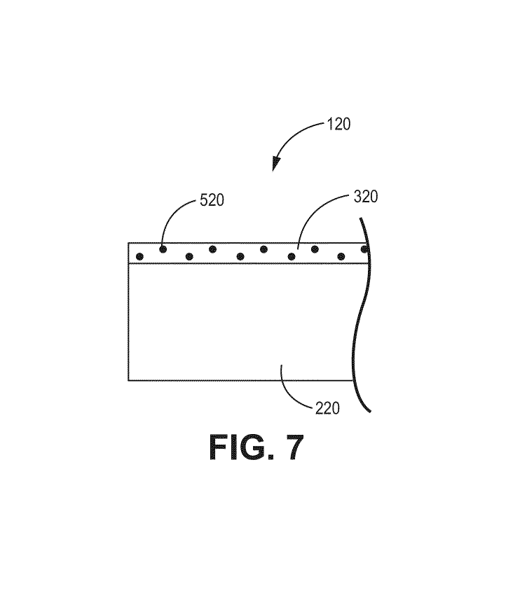

FIG. 7 depicts a schematic cross-sectional view of another laminate consistent with the technology disclosed herein. In this particular embodiment, the laminate 120 has a microporous membrane layer 220, a fine fiber layer 320, and a particulate additive 520 disposed in the fine fiber layer 320. In a variety of embodiments, the particulate additive 520 is colorant particles that are encapsulated by the fine fiber in the fine fiber layer 320, which change the perceived coloration of the fine fiber layer 320. In some embodiments, a colorant additive is not particulate in nature, such as dye colorants, and is nonetheless described herein as encapsulated by the fine fiber. To achieve such a structure, the colorant is added to the polymer solution in the method consistent with the discussion of FIG. 5, above, with minimal impact on fiber morphology as illustrated in the SEM micrograph of FIG. 20, which incorporates a colorant additive that results in a perceived black coloration of the laminate, when compared to FIG. 17.

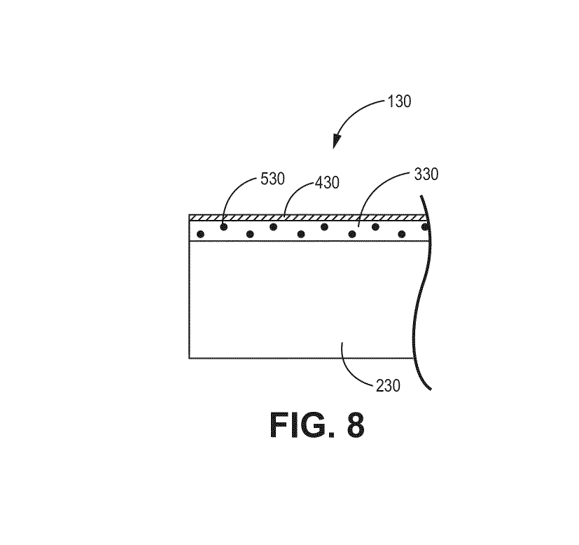

FIG. 8 depicts a schematic cross-sectional view of yet another laminate consistent with the technology disclosed herein. The laminate 130 has a microporous membrane layer 230, a fine fiber layer 330, a functional layer 430, and a particulate additive 530 in the fine fiber layer. In at least one embodiment, the functional layer 430 imparts oleophobicity to the laminate. In a variety of embodiments, the particulate additive 530 is a colorant such as ink. In a variety of embodiments an additive can be disposed in the fine fiber layer that is not particulate in nature.

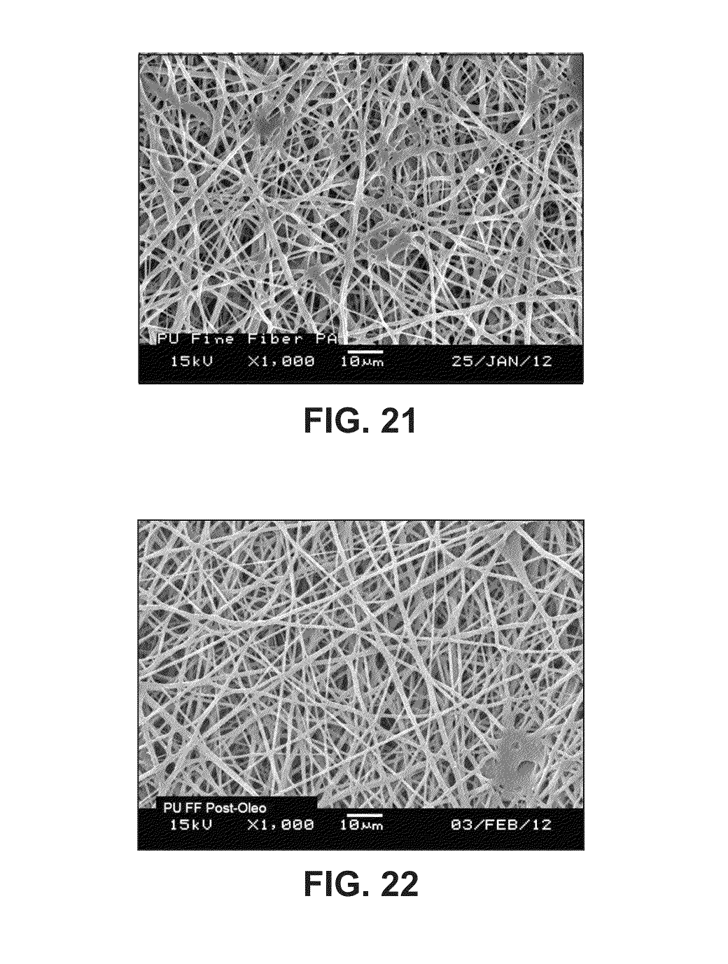

For a variety of the embodiments disclosed herein, there are relatively minimal effects on measures such as Frazier Permeability, fiber morphology, filter efficiency and fiber diameter. FIGS. 21 and 22, for example, depict a polyurethane fine fiber before and after an oleophobic treatment, respectively. Table 1, below, provides efficiency and Frazier permeability data before and after an oleophobic treatment of polyurethane fine fiber samples consistent with FIGS. 21 and 22.

TABLE 1
Oleophobically coated Fine Fiber - Permeability and efficiency results.

| | Before Oleophobic | | After Oleophobic | |
|---|---|---|---|---|
| | Treatment | | Treatment | |
| | | Frazier | Efficiency @ | Frazier |
| | Efficiency @ 0.3 | Permeability | 0.3 micron | Permeability |
| Fiber | micron and 5.0 | [cfm/ft2 | and 5.0 FPM | [cfm/ft2 |
| Samples | FPM [%] | @0.5″H2O] | [%] | @0.5″H2O] |
| PU FF-1 | 89.0 | 11.2 | 96.0 | 11.4 |
| PU FF-2 | 92.8 | 11.8 | 99.7 | 10.1 |

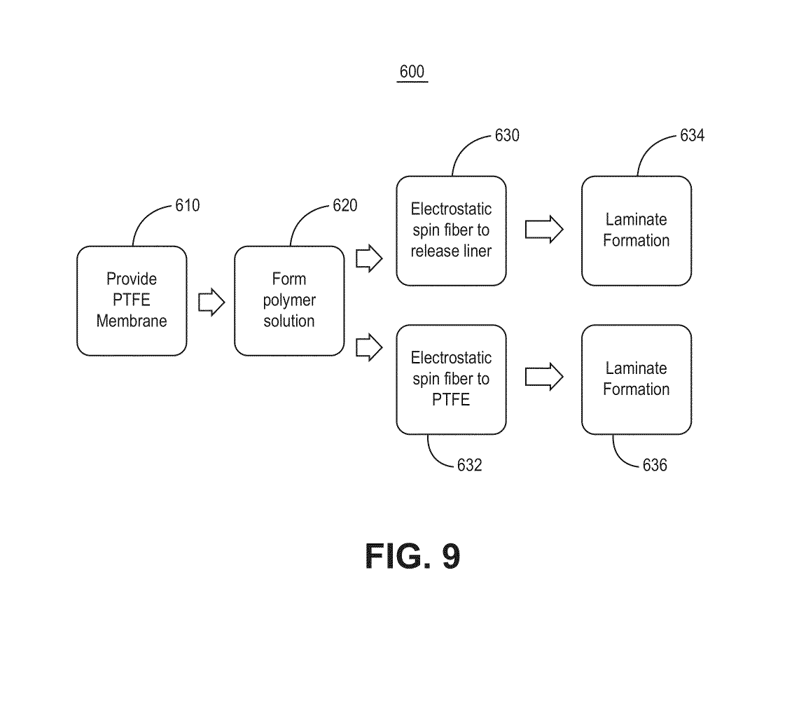

FIG. 9 depicts a flow chart of the processing steps for a laminate, consistent with the technology disclosed herein. A microporous membrane layer is provided at step 610 and a polymer solution is formed at step 620. In one embodiment, the polymer solution is electro-spun at step 630 onto a release liner and then the laminate is formed at step 634. In another embodiment, the polymer solution is electro-spun directly onto the PTFE at step 632 and then the laminate is formed at step 636.

The microporous membrane is generally ePTFE, as described above. The polymer solution is formed at step 620 consistently with the discussion herein, where additives desired within the fine fiber layer are generally added to the polymer solution. In a variety of embodiments, one additive that is used to form the polymer solution 620 is a colorant to influence the coloration of the fine fiber layer.

In one embodiment, the fine fiber layer is electro-spun onto a release liner at step 630. It will be appreciated by those having skill in the art, however, that force-spinning, centrifugal spinning, or meltblowing can also be used to create the fine fiber layer. To form the laminate at step 634, the fine fiber layer is removed from the release liner, any functional layers are added to the fine fiber layer, and the fine fiber layer is laminated to the microporous membrane. As described above, the fine fiber layer can be laminated to the microporous membrane through methods such as calendaring, heat laminating, and the like. In another embodiment, the fine fiber is electro-spun onto the microporous membrane layer at step 632, and the laminate is formed at step 636 with the addition of any functional layers.

As described above, one or more of the functional layers can be a colorant that is applied through dip coating, as one example. The dip coating can be applied at any time after formation of the fine fiber layer. In some embodiments a colorant is added to the polymer solution and is spun with the polymer solution.

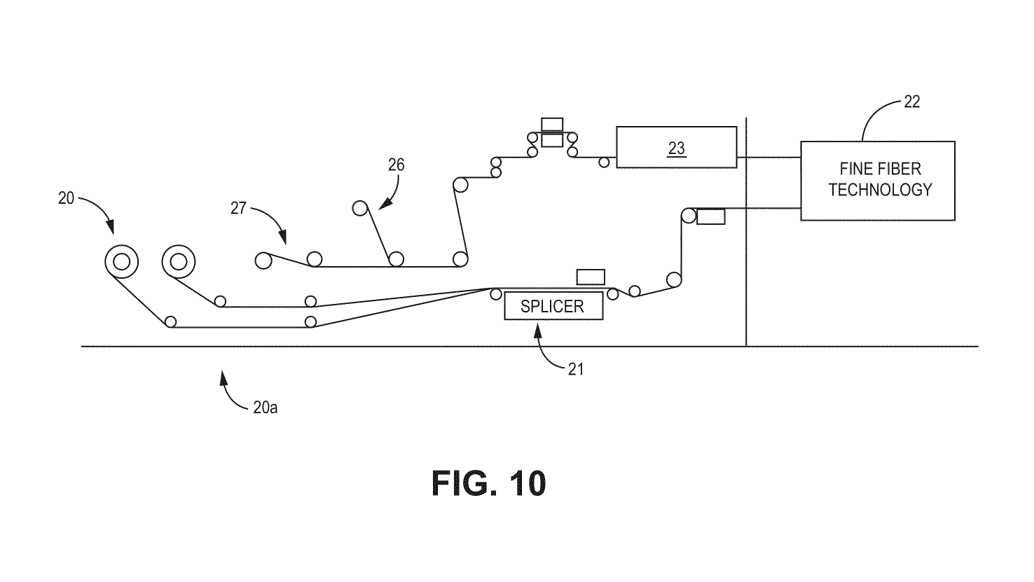

FIG. 10 depicts a system schematic consistent with forming a layer of fine fiber on any type of media. The media is unwound at station 20. The sheet-like substrate 20a is then directed to a splicing station 21 wherein multiple lengths of the substrate can be spliced for continuous operation. The continuous length of sheet-like substrate is directed to a fine fiber technology station 22 comprising the spinning technology of FIG. 5 wherein a spinning device forms the fine fiber and lays the fine fiber in a filtering layer on the sheet-like substrate. After the fine fiber layer is formed on the sheet-like substrate in the formation zone 22, the fine fiber layer and substrate are directed to a heat treatment station 23 for appropriate processing. The sheet-like substrate and fiber layer is then steered to the appropriate winding station to be wound onto the appropriate spindle for further processing 26 and 27. The sheet-like substrate and fine fiber layer can be analyzed offline using an efficiency bench to determine the fine fiber filtration efficiency, as reported in Table 1, above, and an analytical balance to determine the basis weight of the material.

### Embodiments with Molded Portions

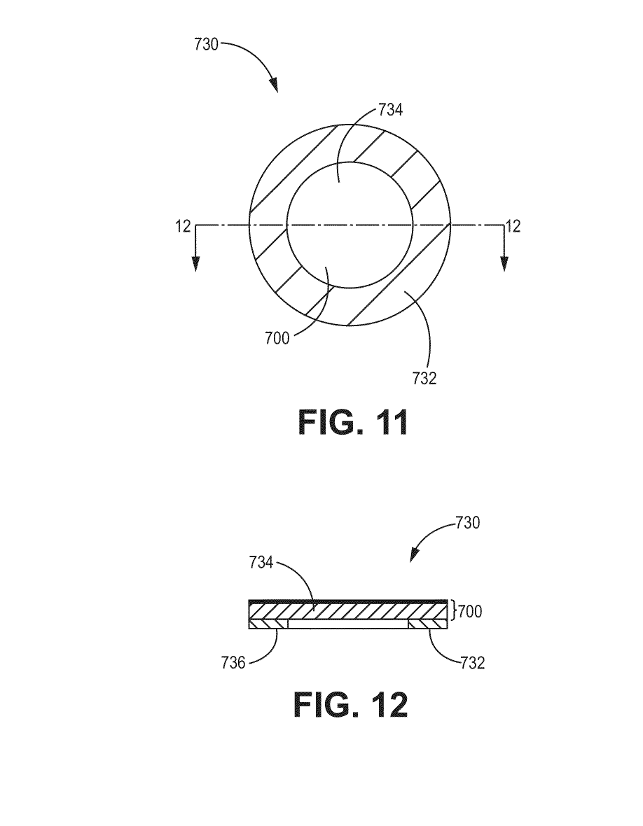

FIG. 11 depicts a front view of an example acoustic venting assembly where a laminate 700 is molded into an acoustic venting assembly 730, and FIG. 12 depicts a cross-sectional view of the acoustic venting assembly 730 in FIG. 11, along the line 12-12 shown in FIG. 11. The acoustic venting assembly 730 generally defines a perimeter region 732 that is configured to couple to an electronics enclosure 50 about the opening 52 (See FIG. 1). The acoustic venting assembly 730 defines an inner region 734 that allows sound transmission through a venting media laminate 700. An injection molded portion 736 is disposed in the perimeter region 732 on one side of the assembly 730. The injection molded portion 736 contacts the laminate 700 and retains it in an extended position. It is also possible for an adhesive layer to be present on the molded portion 736, the opposite side of the assembly 730 or both. The acoustic venting assembly 730 can include additional layers and combinations of layers such as foam layers, adhesive layers, and gasket layers, as is generally known in the art.

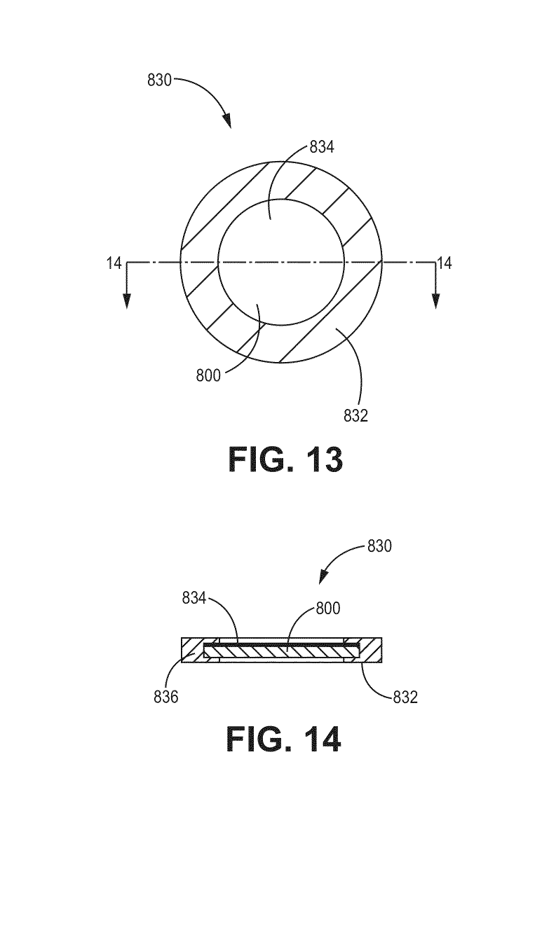

FIG. 13 depicts a front view of an example acoustic venting assembly where a laminate 800 is molded into an acoustic venting assembly 830, and FIG. 14 depicts a cross-sectional view of the acoustic venting assembly 830 in FIG. 13, along the line 14-14 shown in FIG. 13. The acoustic venting assembly 830 generally defines a perimeter region 832 that is configured to couple to an electronics enclosure 50 about the opening 52 (See FIG. 1) and also defines an inner region 834 that allows sound transmission through a venting media laminate 800. An injection molded portion 836 is disposed around the perimeter region 832 of the assembly 830. The injection molded portion 836 surrounds the perimeter edge of laminate 800 and retains it in an extended position. It is also possible for an adhesive layer to be present on one or both sides of the molded portion 836. The acoustic venting assembly 830 can include additional layers and combinations of layers such as foam layers, adhesive layers, and gasket layers, as is generally known in the art.

To form the molded embodiments shown in FIGS. 11-14, the laminate is positioned within an injection molding cavity and injection molding material is introduced into the mold, encapsulating the laminate. Examples of materials that can be used for the molded portions include plastics such as silicones or natural rubber, thermoplastics, such as polypropylene, polyethylene, polycarbonates or polyamides, and thermoplastic elastomers.

It should also be noted that, as used in this specification and the appended claims, the phrase “configured” describes a system, apparatus, or other structure that is constructed or configured to perform a particular task or adopt a particular configuration. The phrase “configured” can be used interchangeably with other similar phrases such as “arranged”, “arranged and configured”, “constructed and arranged”, “constructed”, “manufactured and arranged”, and the like.

All publications and patent applications in this specification are indicative of the level of ordinary skill in the art to which this invention pertains. All publications and patent applications are herein incorporated by reference to the same extent as if each individual publication or patent application was specifically and individually indicated by reference.

This application is intended to cover adaptations or variations of the present subject matter. It is to be understood that the above description is intended to be illustrative, and not restrictive.

1. A venting media laminate comprising:
a microporous membrane layer;
a fine fiber layer directly coupled to the microporous membrane layer; and
a colorant disposed in the fine fiber layer.

2-5. (canceled)

6. The laminate of claim 1, having an average insertion loss no more than 100% more than the average insertion loss of the microporous membrane layer alone in a frequency range from 300 Hz to 4000 Hz.

7-8. (canceled)

9. The laminate of claim 1, wherein the colorant comprises particles encapsulated by the fine fiber.

10. The laminate of claim 1, wherein the colorant is encapsulated by the fine fiber.

11. The laminate of claim 1, wherein the colorant comprises a dip coat on the fine fiber layer.

12. The laminate of claim 1, further comprising one or more functional layers in the fine fiber layer.

13. The laminate of claim 12, wherein the one or more functional layers comprise fluorochemicals.

14-19. (canceled)

20. The laminate of claim 1 wherein when the laminate is disposed across an opening in an enclosure, the enclosure can withstand immersion in 1 meter of water for 30 minutes without the laminate allowing the ingress of water.

21. A method of manufacturing venting media comprising
providing an expanded PTFE membrane;
forming a polymer solution;
spinning the polymer solution to form a fine fiber layer;
adding a colorant; and
laminating the fine fiber layer to the expanded PTFE membrane.

22. The method of claim 21, wherein spinning the polymer solution comprises electro-spinning a fine fiber layer on the expanded PTFE membrane.

23. The method of claim 21, wherein spinning the polymer solution comprises electro-spinning a fine fiber layer on a release liner.

24-27. (canceled)

28. The method of claim 21, wherein adding a colorant comprises mixing the colorant with the polymer solution.

29. The method of claim 21, wherein adding a colorant comprises dip coating the fine fiber layer with the colorant.

30. The method of claim 21, further comprising adding a functional layer, wherein adding a functional layer imparts oleophobicity to the laminate.

31. An acoustic venting laminate comprising:
a microporous membrane layer; and
a fine fiber layer directly coupled to the microporous membrane layer, wherein the acoustic venting laminate has an average insertion loss no more than 100% more than the average insertion loss of the microporous membrane layer alone in a frequency range from 300 to 4000 Hz.

32. The acoustic venting laminate of claim 31, further comprising a colorant.

33-34. (canceled)

35. The acoustic venting laminate of claim 31, further comprising a foam layer.

36. (canceled)

37. The acoustic venting laminate of claim 31, further comprising an adhesive layer on one or both sides.

38-40. (canceled)

41. The acoustic venting laminate of claim 31, wherein the laminate has an average insertion loss no more than 100% more than the average insertion loss of the microporous membrane layer alone in the frequency range from 300 Hz to 4000 Hz.

42-45. (canceled)

46. The acoustic venting laminate of claim 31, wherein the fine fiber layer comprises an average fiber diameter from 0.01 micron to 5.0 micron.

47. (canceled)

48. The acoustic venting laminate of claim 31, wherein the fine fiber layer is self-supporting.

49. (canceled)

50. The acoustic venting laminate of claim 31, further comprising a functional layer, wherein the functional layer imparts oleophobicity to the laminate.

51. The acoustic venting laminate of claim 31, further comprising a molded portion on one or both sides.

52. (canceled)

53. The acoustic venting laminate of claim 31 wherein when the acoustic venting laminate is installed in an opening in an enclosure, the enclosure can withstand immersion in 1 meter of water for 30 minutes without the laminate allowing the ingress of water.
